(19) United States
(12) Patent Application Publication
(10) Pub. No.: US 2026/0289057 A1
(43) Pub. Date: Sep. 24, 2026

(54) SCALABLE AND DYNAMIC MULTI-MODAL CHIP DESIGN HOTSPOT CLASSIFICATION

(71) Applicant: Applied Materials, Inc., Santa Clara, CA (US)

(72) Inventors: Sriram MADHAVAN, Santa Clara, CA (US); Dastagiri DUDEKULA, Eindhoven (NL); Tianchi LIU, Fremont, CA (US); Martinus Maria BERKENS, Waalre (NL)

(73) Assignee: Applied Materials, Inc., Santa Clara, CA (US)

(21) Appl. No.: 19/083,006

(22) Filed: Mar. 18, 2025

(51) Int. Cl. G06F 30/3308; G06N 3/045; G06N 3/0464

(52) U.S. Cl. CPC G06F 30/3308; G06N 3/045; G06N 3/0464

(57) ABSTRACT

Identifying hotspots, or regions on the semiconductor designer substrate that are prone to manufacturing defects or performance issues, requires either error-prone techniques like design rule checking, or resource-intensive techniques such as scanning electron microscopy (SEM) imaging. This disclosure describes training and using a model-based architecture to quickly identify a probability of these hotspots at specific locations. The model is scalable and multi-modal, using inputs of different types (images, tabular, timeseries, etc.) from different sources. Detecting the likelihood of a hotspot can be done very efficiently with this model-based solution and can be used to minimize false positives and negatives before employing more time-intensive inspection techniques.

### TECHNICAL FIELD

This disclosure generally relates to techniques for identifying hotspots on semiconductor substrates. More specifically, this disclosure describes training and using a scalable, dynamic, and multi-modal chip design hotspot classification architecture.

### BACKGROUND

As semiconductor chip designs become increasingly complex, identifying “hotspots”—regions prone to manufacturing defects or performance issues—has become a critical aspect of the design and verification process. Hotspots may arise due to a number of different factors, such as variations in fabrication processes, lithography limitations, suboptimal design choices, and so forth, that lead to excessive heat dissipation, electrical overstress, or layout-dependent effects. Detecting these hotspots early in the design cycle is essential for ensuring high yield, reliability, and overall performance of integrated circuits (ICs). Traditional methods for hotspot identification rely techniques such as design rule checking (DRC) and electromagnetic field (EM) simulations, which are computationally expensive and time-consuming. Alternatively, automated optical inspection (AOI) and scanning electron microscopy (SEM) imaging have been used to verify physical defects that correspond to simulated hotspot predictions.

### BRIEF SUMMARY

In some embodiments, a method for predicting hotspots on semiconductor substrates may include receiving first data associated with a manufacturing a semiconductor substrate, where the first data may include a first data type, and the first data may be associated with a location on the semiconductor substrate. The method may also include receiving second data associated with the manufacturing of the semiconductor substrate, where the second data may include a second data type that is different from the first data type, and the second data may be associated with the location on the semiconductor substrate. The method may additionally include providing the first data and the second data to a trained machine-learning model, where the trained machine-learning model may include a first neural network configured to process data of the first data type, a second neural network configured to process data of the second data type, and an output layer that generates a likelihood of a hotspot at the location on the semiconductor substrate based at least in part on outputs of the first neural network and the second neural network. The method may further include causing an inspection process to be performed at the location on the semiconductor substrate based at least in part on the output of the trained machine-learning model.

In some embodiments, a method of training machine-learning models to generate likelihoods of hotspots at locations on semiconductor substrates may include defining a plurality of configurations for a machine-learning model. Each of the plurality of configurations may define first parameters for a first neural network configured to process first data of a first data type, where the first data may be associated with a manufacturing of a semiconductor substrate and associated with a location on the semiconductor substrate. Each of the plurality of configurations may also define second parameters for a second neural network configured to process second data of a second data type that is different from the first data type, where the second data may be associated with the manufacturing of the semiconductor substrate and associated with a location on the semiconductor substrate. Each of the plurality of configurations may further define connections between components of the machine-learning model including the first neural network and the second neural network. The method may also include training instances of the machine-learning model using each of the plurality of configurations to generate likelihoods of a hotspot at the location on the semiconductor substrate. The method may additionally include identifying a configuration in the plurality of configurations that best determines likelihoods of hotspots on semiconductor substrates. The method may further include using the machine-learning model with the configuration to determine the likelihoods of hotspots on semiconductor substrates.

In some embodiments, a system may include one or more processors and one or more memory devices storing instructions that, when executed by the one or more processors, cause the one or more processors to perform operations including receiving first data associated with manufacturing a semiconductor substrate, where the first data may include a first data type, and the first data may be associated with a location on the semiconductor substrate. The operations may also include receiving second data associated with the manufacturing of the semiconductor substrate, where the second data may include a second data type that is different from the first data type, and the second data may be associated with the location on the semiconductor substrate. The operations may additionally include providing the first data and the second data to a trained machine-learning model. The trained machine-learning model may include a first neural network configured to process data of the first data type, a second neural network configured to process data of the second data type, and an output layer that generates a likelihood of a hotspot at the location on the semiconductor substrate based at least in part on outputs of the first neural network and the second neural network. The operations may further include determining the likelihood of the hotspot at the location on the semiconductor substrate based at least in part on an output of the trained the machine-learning model.

In any embodiments, any and all of the following features may be implemented in any combination and without limitation. The inspection process may include performing an eBEAM Wafer Inspection (EBI) at the location on the semiconductor substrate based on the likelihood of the hotspot at the location. The inspection process may include an Optical Wafer Inspection (OPWI) being performed on the semiconductor substrate, and correlating a result of the OPWI at the location with the likelihood of the hotspot at the location to reduce the probability of a false positive. The first data may include images based on a layout design file for the semiconductor substrate. The first neural network may include a convolutional neural network (CNN) configured to identify features in the images of the semiconductor substrate that are associated with hotspots. The second data may include tabular data from a design file for the semiconductor substrate. The second data may include tabular data from a metrology file for the semiconductor substrate. The second neural network may include an attention-based neural network configured to process tabular data. The first parameters may include a dimension of an output of the first neural network. The first parameters may include a number of hidden layers of the first neural network. The connections between the components of the machine-learning model may include the first neural network and the second neural network processing data in parallel; and outputs of the first neural network and the second neural network being combined in a set of fully connected layers that generate an output of the likelihood of the hotspot at the location on the semiconductor substrate. The connections between the components of the machine-learning model may include the first neural network and the second neural network processing data sequentially; and an output of the first neural network being combined with the second data to be processed by the second neural network before being processed by a set of fully connected layers that generate an output of the likelihood of the hotspot at the location on the semiconductor substrate. The connections between the components of the machine-learning model may include the first neural network and the second neural network processing data sequentially; an output of the first neural network being combined with the second data to be processed by the second neural network; and an output of the second neural network being combined with the output of the first neural network in a set of fully connected layers that generate an output of the likelihood of the hotspot at the location on the semiconductor substrate. The connections between the components of the machine-learning model may include the first neural network and the second neural network processing data in parallel; and outputs of the first neural network and second neural network being combined in a second instance of the second neural network that generates an output of the likelihood of the hotspot at the location on the semiconductor substrate. Identifying the configuration in the plurality of configurations that best determines the likelihood of the hotspot may include maximizing a product of a true negative rate and a true positive rate. The second data may include time series data from a semiconductor processing chamber used in the manufacturing of the semiconductor substrate. The semiconductor substrate may be subdivided into a plurality of locations that include the location on the semiconductor substrate, and each of the plurality of locations may include a rectangular subdivision of the semiconductor substrate. The first data may be received from a first data source, and the second data may be received from a second data source that is different from the first data source.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 illustrates a flowchart of a method for predicting hotspots on semiconductor substrates, according to some embodiments.

FIG. 2A shows a simplified block diagram of a data flow for using a multi-modal model, according to some embodiments.

FIG. 2B illustrates how the probability outputs from the model may be used in a workflow for identifying hotspots, according to some embodiments.

FIG. 3 illustrates a flowchart of a method for training machine-learning models to generate likelihoods of hotspots at locations on semiconductor substrates, according to some embodiments.

FIG. 4 illustrates a configuration of a model for a parallel hybrid architecture, according to some embodiments.

FIG. 5 illustrates a configuration of a model for a sequential hybrid architecture, according to some embodiments.

FIG. 6A illustrates a configuration of a model for a sequential architecture with a skip connection, according to some embodiments.

FIG. 6B illustrates a configuration of a model for a parallel architecture using a second tabular network, according to some embodiments.

FIG. 7 illustrates tables of results from testing a plurality of different model configurations, according to some embodiments.

FIG. 8 illustrates a table showing the performance difference between multi-modal models in comparison to models with only a single type of input, according to some embodiments.

FIG. 9 illustrates an exemplary controller, in which various embodiments may be implemented.

### DETAILED DESCRIPTION

Identifying “hotspots,” or regions on the semiconductor design or substrate that are prone to manufacturing defects or performance issues, requires either error-prone techniques like design rule checking, or resource-intensive techniques such as scanning electron microscopy (SEM) imaging. This disclosure describes training and using a model-based architecture to quickly identify a probability of these hotspots at specific locations. The model is scalable and multi-modal, using inputs of different types (images, tabular, timeseries, etc.) from different sources. Detecting the likelihood of a hotspot can be done very efficiently with this model-based solution and can be used to minimize false positives and negatives before employing more time-intensive inspection techniques.

As semiconductor chip designs become increasingly complex, identifying hotspots has become a critical aspect of the design and verification process. Hotspots may arise due to a number of different factors, such as variations in fabrication processes, lithography limitations, suboptimal design choices, and so forth, that lead to excessive heat dissipation, electrical overstress, or layout-dependent effects. For example, a hotspot may result from a complex pattern that is to be fabricated on integrated circuit die. However, given the limitations of existing manufacturing processes (e.g., lithography, deposition, polishing, etch, etc.) these pattern designs may result in incorrectly implemented integrated circuits. More broadly, a hotspot be classified as a location on an integrated circuit die that is especially sensitive to defects or manufacturing issues.

Detecting these hotspots early in the design cycle is essential for ensuring high yield, reliability, and overall performance of integrated circuits (ICs). Semiconductor chip design hotspots may result in significant functional and parametric yield loss. Therefore, it may be crucial to identify and address these hotspots early in the chip design and manufacturing process to minimize the impact on cost, performance, and time-to-market. While various Design for Manufacturing (DFM) flows have been developed to detect hotspots, they have limitations given the continuous technology scaling and increasing complexity of chip design and manufacturing interactions.

The embodiments described herein overcome these limitations, by using a new hotspot detection methodology and flow based on multimodal machine learning. This methodology may utilize data from diverse sources, including chip design, wafer metrology, and manufacturing equipment signals. These techniques may also handle different types of inputs, such as images and tabular features. By integrating data from these sources into a single trainable deep learning network, a system may automatically learn and adjust the relative weightings of any or all features during the machine learning model training process.

The techniques described herein may differ from other ML-based detection techniques in that the model is trained to be multi-modal. In other words, the model is configured to receive data from a variety of different modalities. These modalities may include image-based data, tabular features extracted from the chip design or measured from wafers, timeseries data from tool sensors, and/or any other data format. In another sense, the model may be configured to receive data from a variety of different data sources, including design files, live sensor measurements, metrology imagery, process history data, recipes and settings, and so forth. Unlike previous techniques that were limited to either a single data source for a single modality, the techniques described herein are not fixed or static, but can instead be scaled and dynamically adjusted to combine different data types and sources.

The architectures described herein are also dynamic in the sense that the number of inputs and types of inputs are not limited by the model architecture. Instead, these different types of inputs can be simultaneously combined without limitation (aside from the practical limitations imposed by available computing resources and training time).

Additionally, these architectures may be described as dynamic, since data from all modalities may be combined into a single, universal, deep-learning network. The relative weightings of all sources of data for hotspot classification inference are fully learnable using supervised training of the model with labeled data. The attributes of the architecture, such as output dimensions of each network stage before fusing, layer depths, etc., are also fully parameterized and automatically learnable through automated neural architecture search spaces.

These multimodal, model-based techniques may also be fully compatible with existing workflows. For example, one workflow may use optical wafer inspection (OPWI) to identify problematic areas on a particular substrate. More intensive eBEAM Wafer Inspection (EBI) may then be performed at the specific locations identified by the OPWI. The model-based techniques may be used to minimize the false positives and false negatives that may be generated by the OPWI process, and the probabilities output from the model may be used to more efficiently identify locations for subsequent EBI analysis.

The following discussion will first describe using a trained multi-modal model to generate a probability of hotspots at a particular location on a semiconductor substrate. Then, the remaining disclosure will describe methods for optimizing and training the model, along with different model architectures that may be used in different situations.

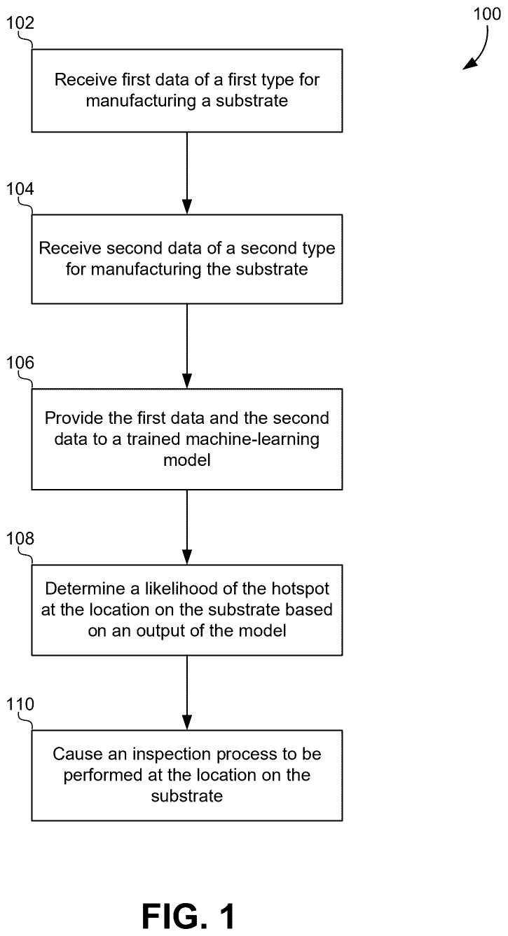

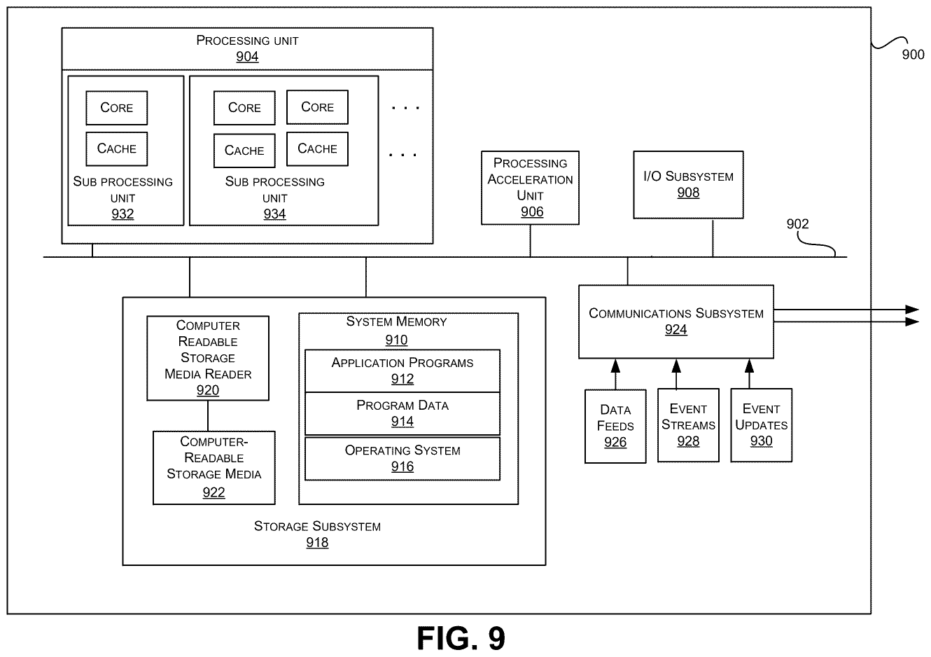

FIG. 1 illustrates a flowchart of a method 100 for predicting hotspots on semiconductor substrates, according to some embodiments. This method may be carried out by a computer system, such as a controller for a semiconductor processing chamber, a metrology station, a server in a manufacturing facility, and/or any other computing system. For example, the computing system may include one or more processors that may be co-located or distributed between different locations, such as between a controller and a local server. The computing system may also include one or more memory devices that store instructions for the one or more processors. These memory devices (e.g., memory caches, instruction memories, flash memories, etc.) may also be distributed or co-located with the one or more processors in any combination and of any location. As described below in FIG. 9, these instructions may cause the one or more processors to perform some or all of the operations described below.

The method may include receiving first data associated with a manufacturing a semiconductor substrate (102). The first data may include a first data type, and the first data may be associated with a location on the semiconductor substrate. Since the system is multi-modal, the method may also include receiving second data associated with the manufacturing of the semiconductor substrate (104). The second data may include a second data type that is different from the first data type, and the second data may also be associated with the same location on the semiconductor substrate.

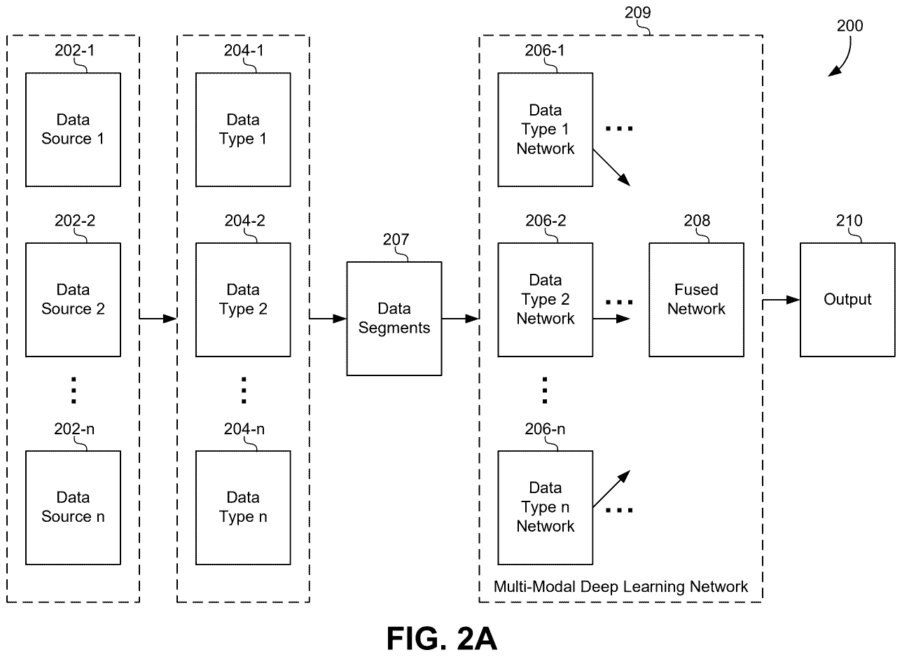

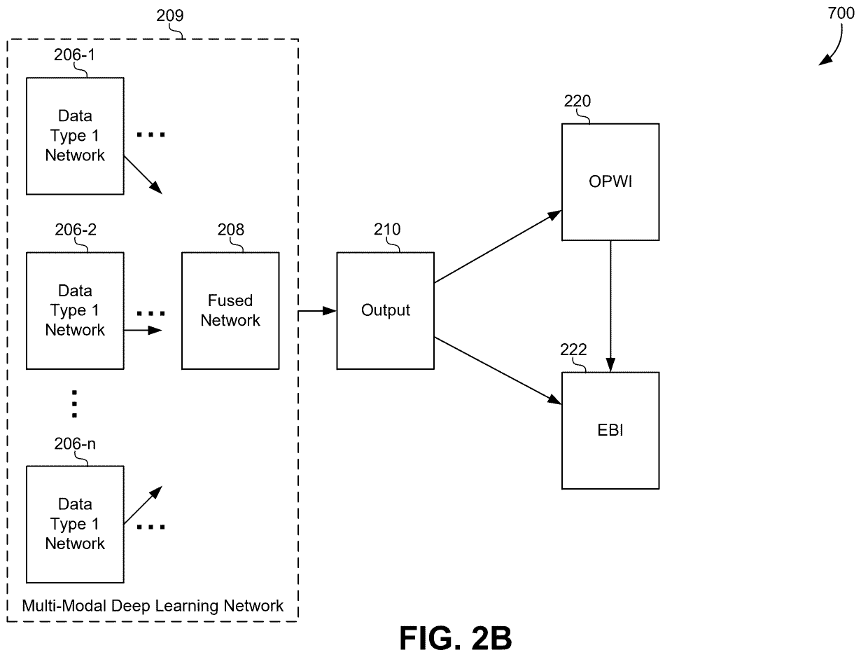

To illustrate, FIG. 2A shows a simplified block diagram 200 of a data flow for using a multi-modal model, according to some embodiments. The system may receive inputs from a plurality of different data sources 202. These data sources may come from different processing stations, different computer systems, different sensors, and/or different stages in the manufacturing process. For example, a first data source may include design files or other design specifications for the semiconductor substrate. This design data may include layout images, feature definitions, mask or circuit layouts, and/any other information from a substrate design file. A second data source may include data from the semiconductor substrate itself. This substrate data may include metrology data from a metrology station, electrical data from electrical testing procedures, a process history listing results of various semiconductor manufacturing processes, and so forth. A third data source may include data collected from various semiconductor manufacturing tools. The tool data may include sensor data (e.g., temperature, pressure, gas flow, gas species measurements, power measurements, timing, etc.), tool settings (e.g., voltage settings, current settings, flow regulator settings, heater settings, etc.), and/or extracted features from the tools used in the manufacturing process. More generally, the first data may be received from a first data source, and the second data may be received from a second data source that is different from the first data source.

Each of the plurality of different data sources 202 may provide data in different formats or datatypes. For example, design data may provide data in the form of high-resolution images of the design layout, as well as tabular data identifying dimensions of the various features. In another example, metrology data may provide images of the substrate, as well as tabular data in the form of measurements performed on the substrate. The tool data from tool data sources may include tabular data as well as time series data from a semiconductor processing chamber used in the manufacturing of the substrate. Therefore, the data provided from the plurality of data sources 202 may include a plurality of different data types 204 in any combination. A single data source may provide data in a plurality of different datatypes. Conversely, a plurality of different data sources may each provide data of a single data type (e.g., image data). The first data and the second data may both be received from the same data source, but may still be formatted as different data types. As a multi-modal model, the system is compatible with any combination of data sources and/or datatypes.

After receiving data from various data sources and/or in different data type formats, the multi-modal system may segment the data into data segments 207 that correspond to specific locations on the substrate. For example, the substrate may be subdivided into a plurality of locations, such as rectangular or square subsections of the substrate. In some embodiments, each subdivision may be 100 nm×100 nm square. The dimensions may also include between 25 nm and 50 nm square, between 50 nm and 100 nm square, between 100 nm and 200 nm square, between 200 nm and 500 nm square, and up to 1000 nm square. These rectangular/square subdivisions may be correlated with specific data segments 207 in the data inputs. For example, images of the substrate may be subdivided into smaller images that correspond to each of these locations on the substrate. Tabular data may also be subdivided (if possible) to be specifically related to each location on the substrate. For example, tables of metrology measurements may be taken at locations on the substrate, and these measurements may be subdivided into tabular segments that are each associated with a specific location.

By subdividing the data inputs into data segments related to specific locations, the model may then perform an inference operation on each set of data segments. The output 210 of the model may generate a probability of a hotspot at the specific location that is correlated with the data segment inputs. For example, providing image data of a specific location to the model 209 may generate an output 210 indicating a probability of a hotspot at that location. The model 209 may sequentially process each of the data segments 207 and generate an output 210 associated with each of the data segments 207. After looping through each of the data segments 207, the model 209 will have produced a sequence of outputs 210, each of which may include a probability of a hotspot at each subdivided location on the substrate.

The method 100 may also include providing the first data and the second data to a trained machine-learning (ML) model (106). The model 209 may include a first neural network configured to process data of the first data type, and a second neural network configured to process data of the second data type. In order to handle the different datatypes that may be presented to the model 209, the model 209 may include a plurality of different networks that are each configured to handle one of the data types. For example, some embodiments may use a convolutional neural network to analyze image data. A Convolutional Neural Network (CNN) analyzes image data by applying a series of convolutional filters to extract hierarchical features such as edges, textures, shapes, and complex patterns that may be associated with hotspots through a training process. The CNN begins with convolutional layers, where small, learnable filters scan the image, detecting local features while preserving spatial relationships. These feature maps may then be passed through activation functions in intermediate or hidden layers, each of which may further refine the hotspot features being identified. As described in greater detail below, the output of the image CNN may provide the extracted hotspot features to a set of fully connected layers or another type of neural network that may map the features to classification labels to generate a probability of a hotspot. This hierarchical approach makes CNNs highly effective for hotspot classification from image data. Each image data type in the data segments 207 may be provided to a corresponding CNN in the model 209.

In another example, tabular data may be processed by an attention-based neural network configured to process tabular data (i.e., a “tabular network”). Since tabular data may be composed of structured numerical and categorical features commonly found in databases and spreadsheets. Unlike traditional neural networks that process all input features simultaneously, a tabular network may use a sequential attention-based mechanism to selectively focus on the most relevant features at each decision step. As one non-limiting example, TabNet may be used by some embodiments to process tabular data. In contrast to a CNN, a tabular network may use the attention-based feature selection process instead of convolution to dynamically identify which tabular features are the focus of each processing layer. Time series data may also be organized into a table and processed by a tabular network. Each tabular data type in the data segments 207 may be provided to a corresponding tabular network in the model 209.

More generally, each data type in the data segments 207 may be associated with a specific input network in the model 209 configured to process that type of data. Thus, the model 209 may include a plurality of different neural networks 206 at the input of the model 209, each of which corresponds to a specific data type provided by the data segments 207. This organization allows the model 209 to be extensively scalable to accommodate any number of data types from any number of data sources. For example, adding a new data type may be incorporated into the model 209 by providing that data type as an input to the model 209, and adding a corresponding neural network in the plurality of different neural networks 206 at the input of the model 209 that is specifically configured to handle that data type.

Each of the plurality of different neural networks 206 may generate individual outputs that identify hotspot features based on the input data types. The model 209 may combine the outputs of the plurality of different neural networks 206 by feeding their final feature representations into a single, fused network 208. For example, the feature representations from each of the different neural networks 206 may be combined into a shared set of fully connected layers, which act as a final decision-making mechanism for the model 209. Each of the plurality of different neural networks 206 (e.g., CNNs for image data, recurrent neural networks (RNNs) for sequential data, TabNet for tabular data, etc.) may independently extract high-level features from their corresponding data type inputs. These extracted feature vectors may then be concatenated or otherwise combined into single high-dimensional representations, which may be passed to a set of fully connected layers or any other fused network 208. These final layers may integrate information from the outputs of the different neural networks 206, learning complex relationships between each of the extracted features. This allows the features from different data types in the multi-modal system to each be processed by specialized networks, and then merged for a final prediction of a hotspot at the corresponding location on the substrate.

The method 100 may also include determining the likelihood of the hotspot at the location on the semiconductor substrate based at least in part on an output of the trained the model (108). For example, the model 209 may generate an output layer that generates a likelihood of a hotspot at the location on the semiconductor substrate based at least in part on outputs of the first neural network and the second neural network, which may be combined using the fused network 208 described above. The output 210 may include a binary representation of whether a hotspot is likely to be located at that specific location. For example, a logic “0” output may indicate that a hotspot is not likely to be located at a specific location, while in “1” may indicate a likely hotspot that should be further investigated by additional processes or tools. In other embodiments, the output 210 may include a scalar or probability, for example, between 0.0 and 1.0. Since each of the data segments 207 may generate an individual output 210, this output 210 may be correlated with the specific location on the substrate associated with the input data segment. When each of the data segments 207 have been processed, a corresponding set of outputs may be used to map specific hotspot probabilities to each location on the substrate.

The method 100 may further include causing an inspection process to be performed at the location on the semiconductor substrate based at least in part on the output of the trained machine-learning model (110). FIG. 2B illustrates how the probability outputs from the model 209 may be used in a workflow for identifying hotspots, according to some embodiments. As described above, the probabilities generated by the output 210 may be used to control or trigger additional inspection processes in the semiconductor manufacturing workflow. For example, the probabilities may be provided to an OPWI process, where an optical wafer inspection may be performed. Optical wafer inspection is a process in semiconductor manufacturing used to detect defects, contamination, and patterning errors on silicon wafers. It involves scanning wafers using high-resolution optical imaging systems that capture microscopic details of the wafer surface. OPWI systems compare the captured images to a reference image or design specifications to identify anomalies that may be indicative of hotspots, such as lithography misalignment or structural defects. OPWI is widely used in front-end wafer fabrication (lithography, deposition, etching) as well as in back-end assembly and packaging.

The output 210 representing probabilities of hotspots can be provided to the OPWI system 220 and used to verify or refine the possible defect locations detected by the OPWI system 220. For example, the OPWI system 220 may generate false negatives or false positives, depending on the wafer design. The output 210 may be correlated with locations in the output of the OPWI system 220. If the output 210 indicates a high probability of a hotspot in a location where the OPWI system 220 does not indicate a defect, this location may be flagged as a false negative and subject to more in-depth inspection. Conversely, if the output 210 indicates a very low probability of a hotspot in a location where the OPWI system 220 does indicate a defect, this location may be flagged as a false positive and not subject to further inspection, depending on the degree of certainty provided by the output 210 of the model 209. Thus, combining the output 210 from the model 209 with the results of the OPWI system 220 may prevent critical defects from escaping detection and may reduce the number of locations that are subject to a more rigorous inspection technique.

In some embodiments, additional inspection may be performed using eBEAM Wafer Inspection (EBI), which is an advanced semiconductor inspection technique that uses a focused beam of electrons to scan the surface of a wafer, detecting defects at nanometer-scale resolutions. Unlike optical inspection, which is limited by the diffraction of light, eBEAM inspection can identify sub-wavelength defects, electrical faults, and process variations that may impact semiconductor device performance. EBI operates by scanning the wafer with an electron beam and generating secondary or backscattered electrons that provide high-contrast imaging of surface features. This technique is particularly effective in detecting open circuits, short circuits, and patterning issues in advanced nodes where feature sizes are extremely small. Due to its high resolution, eBEAM inspection is particularly well-suited for hotspot detection by identifying regions on a semiconductor substrate that are particularly susceptible to defects due to lithographic limitations, process variability, or design constraints. However, eBEAM systems are slower than optical inspection tools due to serial scanning. Therefore, it is important to limit the number of eBeam inspection locations in order to avoid affecting the throughput of the workflow.

The output 210 from the model 209 may be used to optimize the number of locations subjected to EBI. As described above, the potential defect locations identified by the OPWI system 220 may be used to identify locations for inspection by the EBI system 222. The output 210 may refine these locations identified by the OPWI system 220 before sending these locations to the EBI system 222. Alternatively or additionally, the output 210 from the model 209 may be used to identify locations for inspection by the EBI system 222 even without using the OPWI system 220. For example, locations with an output 210 above a threshold probability may be subjected to inspection by the EBI system 222, and locations with an output 210 below a threshold probability need not be subjected to inspection by the EBI system 222. Therefore, the output 210 may optimize the use of the EBI system 222 to only inspect locations with a high probability of including a hotspot.

It should be appreciated that the specific steps illustrated in FIG. 1 provide particular methods of using a multi-modal model to identify hotspots according to various embodiments. Other sequences of steps may also be performed according to alternative embodiments. For example, alternative embodiments may perform the steps outlined above in a different order. Moreover, the individual steps illustrated in FIG. 1 may include multiple sub-steps that may be performed in various sequences as appropriate to the individual step. Furthermore, additional steps may be added or removed depending on the particular applications. Many variations, modifications, and alternatives also fall within the scope of this disclosure.

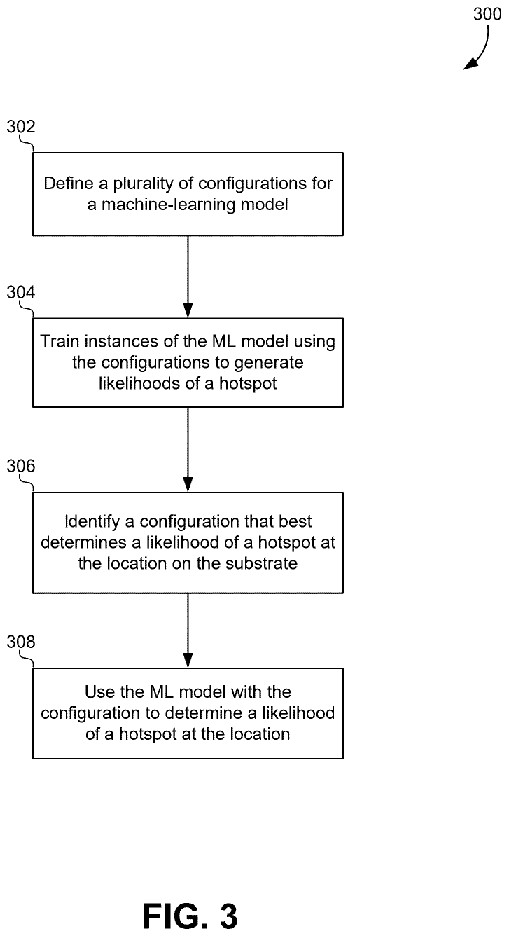

FIG. 3 illustrates a flowchart of a method 300 for training machine-learning models to generate likelihoods of hotspots at locations on semiconductor substrates, according to some embodiments. Due to the variations in substrate designs, substrate manufacturing processes, and process variability, a single design of the machine-learning model is unlikely to be universally optimal for all designs. As described above, the embodiments described herein are scalable and dynamic such that they may accommodate any type or number of inputs. Therefore, designing the model itself may involve the following techniques that improve the model performance when identifying the likelihood of a hotspot at locations on the substrate.

The method 300 may include defining a plurality of configurations for a machine-learning model (302). Each configuration for the model may include first parameters for a first neural network configured to process first data of a first data type, and second parameters for a second neural network configured to process second data of a second data type that is different from the first data type. As described above, these data may be segmented into subdivisions on the wafer such that each data set is associated with the manufacturing of the semiconductor substrate and with a specific location on the semiconductor substrate. Each configuration may also describe connections between components of the model, such as connections between the first neural network, the second neural network, and/or any other network in the model.

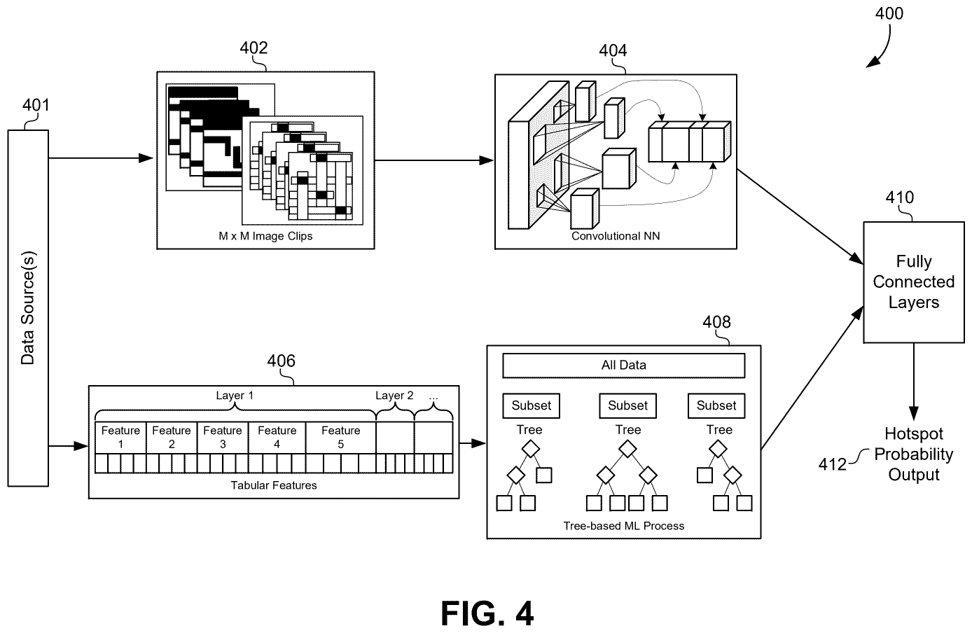

FIG. 4 illustrates a configuration of a model 400 for a parallel hybrid architecture, according to some embodiments. The data sources 401 may include M×M (e.g., 100 nm×100 nm) images 402 of the substrate from a metrology process or from a design file. The data sources 401 may also include tabular data 406. In order to handle these different types of data inputs, the model 400 may include a CNN 404 to process the images 402 and a tabular network 408 to process the tabular data 406. These may represent a first network and a second network processing data in parallel. The outputs of these networks may then be combined in a set of fully connected layers 410 that generates an output 412 of the likelihood of the hotspot at the location on the semiconductor substrate. Therefore, the configuration for this model 400 may include information such as a dimension of the output of the first network (e.g., the CNN 404), a number of hidden layers in the CNN 404, a dimension of the output of the second network (e.g., the tabular network 408), a number of internal layers of the tabular network 408, connections between the CNN 404, the fully connected layers 410, and the tabular network 408, and so forth.

When optimizing and training the model to best detect hotspots, the system may build different versions of the model using different configurations. For example, these different configurations may change the number of output dimensions, the number of internal layers, and the connections between the different internal networks. The CNN 404 represents one possible implementation of the model that may be built, trained, and compared to other similar models using different configurations. The following figures illustrate additional example models that may be built using different configurations of the CNN 404 and the tabular network 408. Specifically, these examples use different connections between these networks and any fused layers. A method of comparing these different models using different configurations to identify an optimal configuration will then be described.

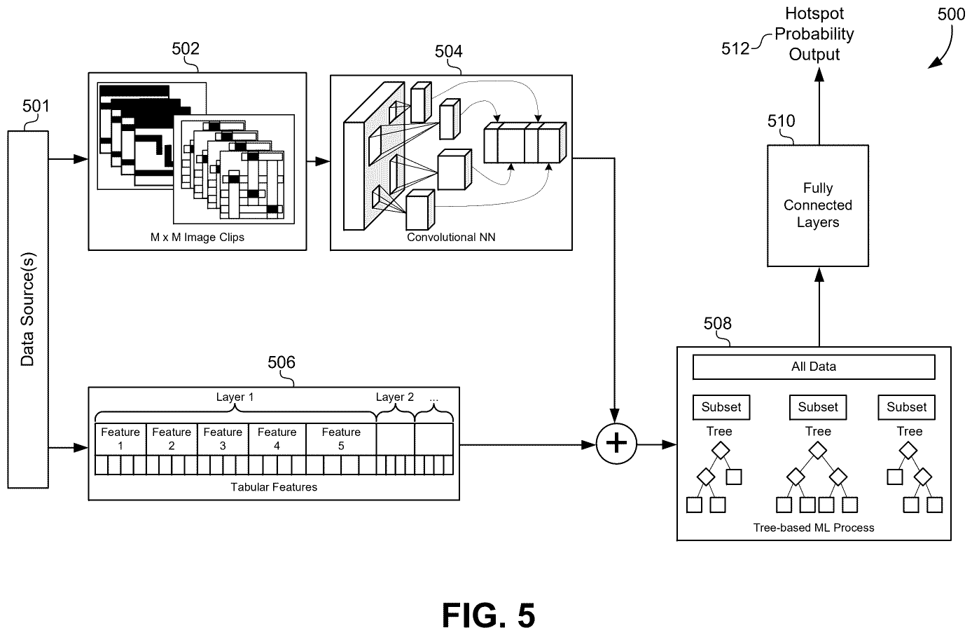

FIG. 5 illustrates a configuration of a model 500 for a sequential hybrid architecture, according to some embodiments. The data sources 501 may include M×M (e.g., 100 nm×100 nm) images 502 of the substrate from a metrology process or from a design file. The data sources 501 may also include tabular data 506. In order to handle these different types of data inputs, the model 500 may include a CNN 504 to process the images 502 and a tabular network 508 to process the tabular data 506. These may represent a first network and a second network processing data in parallel. However, instead of processing image data and tabular data in parallel, this model 500 may perform these processing steps sequentially in series. For example, the output of the CNN 504 may be merged with the tabular data 506. The resulting tabular data from this merge operation may then be processed by the tabular network 508. Finally, the output of the tabular network 508 may be provided to a set of fully connected layers 510 that generates an output 512 of the likelihood of the hotspot at the location on the semiconductor substrate. Therefore, the configuration for this model 500 may include information such as a dimension of the output of the first network (e.g., the CNN 504), a number of hidden layers in the CNN 504, a dimension of the output of the second network (e.g., the tabular network 508), a number of internal layers of the tabular network 508, the fully connected layers 510, and the tabular network 508, and so forth. In contrast to the model 400, this model 500 may also include the serial connections between the CNN 504 and the tabular network 508 instead of using a parallel connection as described above.

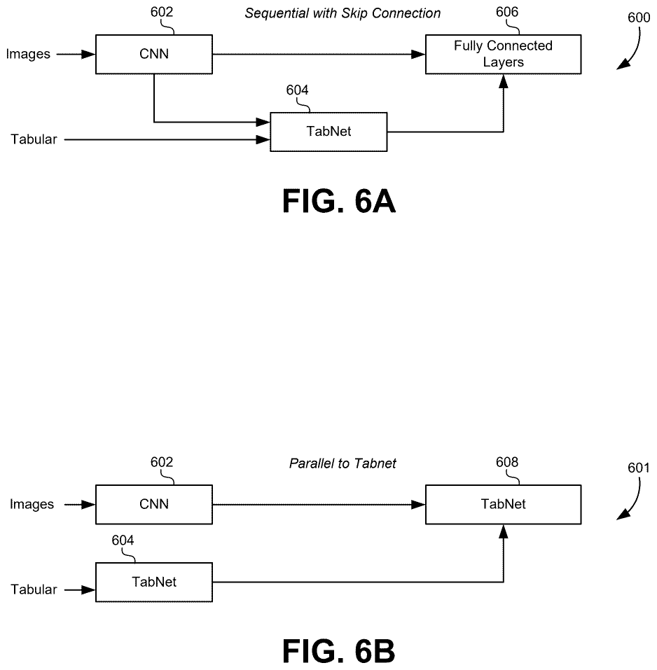

FIG. 6A illustrates a configuration of a model 600 for a sequential architecture with a skip connection, according to some embodiments. Some of the details described above in FIG. 4 and FIG. 5 have been omitted from FIG. 6A for the sake of clarity, however it should be assumed that these details are present although not explicitly shown. For example, a CNN 602 may receive image data as described above. The output of the CNN 602 may be merged with the tabular input data as in FIG. 5, and the merged data may be provided as an input to a tabular network 604. However, the output of the CNN 602 may also be provided as input to a set of fully connected layers 606 along with the output of the tabular network 604. Stated more generally, a first network (e.g., the CNN 602) and a second network (e.g., the tabular network 604) may process data sequentially, such that an output of the first neural network may be combined with second data (e.g., the tabular data) to be processed by the second neural network. An output of the second neural network may then be combined with the output of the first neural network in a set of fully connected layers that generate an output of the likelihood of the hotspot at the location on the semiconductor substrate. Thus, the configuration for the model 600 may include the sequential connections described above in FIG. 5 along with an additional skip connection feeding the output of the CNN 602 into the fully connected layers 606. The configuration may also include the other parameters of the model, such as dimensions of the output of each network, a number of hidden layers, and so forth.

FIG. 6B illustrates a configuration of a model 601 for a parallel architecture using a second tabular network 608, according to some embodiments. Some of the details described above in FIG. 4 and FIG. 5 have been omitted from FIG. 6A for the sake of clarity, however it should be assumed that these details are present although not explicitly shown. For example, a CNN 602 may receive image data, and a tabular network 604 may receive tabular data as described above. Instead of using a set of fully connected layers, the output of the CNN 602 may be merged with the output of the tabular network 604 and provided as an input to the second tabular network 608. Stated more generally, a first network (e.g., the CNN 602) and a second network (e.g., the tabular network 604) may process data in parallel. Outputs of the first neural network and second neural network may the be combined in a second instance of the second neural network (e.g., the second tabular network 608) that generates an output of the likelihood of the hotspot at the location on the semiconductor substrate. Thus, the configuration for the model 601 may include the parallel connections described above in FIG. 4 along with an additional connection to the second instance of the tabular network 608. The configuration may also include the other parameters of the model, such as dimensions of the output of each network, a number of hidden layers, and so forth.

Turning back briefly to FIG. 3, the method 300 of training ML models to generate likelihoods of hotspots may further include training instances of the model using each of the plurality of configurations to generate likelihoods of a hotspot at the location on the semiconductor substrate (304). In order to accurately identify an optimal model configuration for processing the multi-modal data provided to the model, the system may generate a plurality of different models having different configurations. These configurations may include the connections/architectures of models described above in FIG. 4, FIG. 5, and FIGS. 6A-6B, along with any other model architectures not described explicitly herein. Each model architecture may also include multiple instances, each of which may vary the number of dimensions in each model, the number of hidden layers each model, and along with any other parameters. Thus, a large number of potential models may be generated, each using a different configuration.

Each of these model configurations may then be trained using historical data in a supervised training methodology where the training data is labeled. For example, historical data from previous semiconductor substrate manufacturing processes may be used as training data. This historical data may include design files, tool data recorded during the manufacturing process (e.g., sensor readings, voltage settings, temperatures, pressures, etc.), metrology data, and any other input data described above. The labels may include information from the EBI and/or OPWI processes that actually identify whether a hotspot was located at a particular location on the substrate. The training process may adjust the individual weights in each of the individual neural networks in the model, as well as weightings of the outputs of these networks when being combined or routed within the model.

The method 300 may further include identifying a configuration in the plurality of configurations that best determines a likelihood of a hotspot at the location on the semiconductor substrate (306). In order to identify an optimal configuration that best determines a likelihood of a hotspot, the trained models may each be tested using a variety of different test cases that span various processes, technologies, and hotspot defect types. The model outputs across all of the test cases may be analyzed to calculate false positives, true positives, false negatives, true negatives, and other statistical metrics that may be used to compare these different model configurations in terms of accuracy and precision.

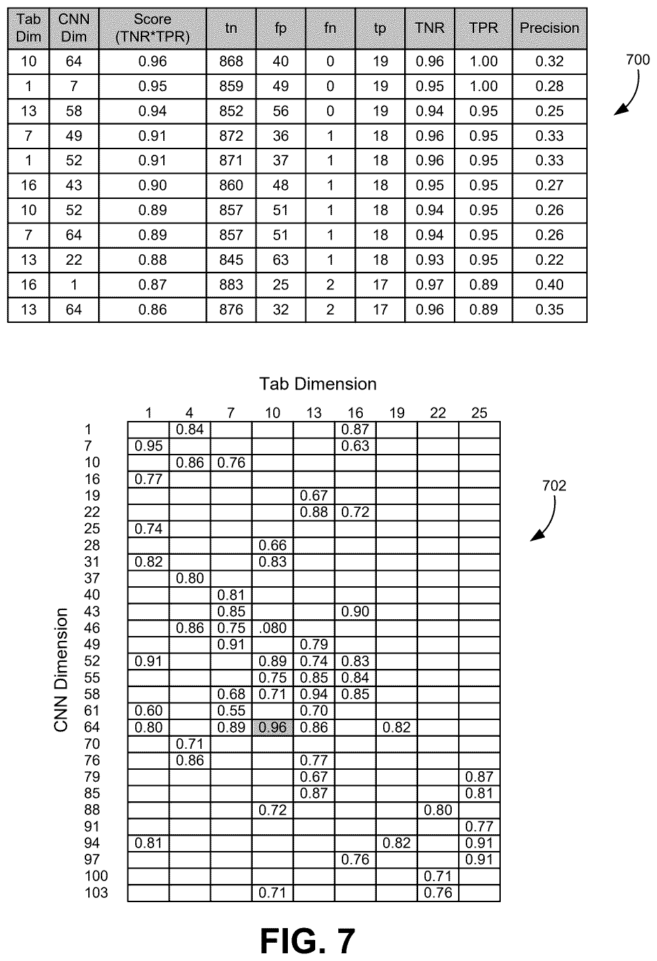

FIG. 7 illustrates tables of results from testing a plurality of different model configurations, according to some embodiments. The table 700 illustrates how different combinations of the output dimensions in the CNN and the output dimensions of the tabular network affect the overall performance of the model in detecting hotspots. As illustrated, different combinations of tabular output dimensions (“Tab Dim”) and CNN output dimensions (“CNN Dim”) generate different scores based on a combination of different statistical metrics. In this example, each model configuration can be run against the test inputs to generate a number of true negatives (“tn”), false positives (“fp”), false negatives (“fn”), and true positives (“tp”). These metrics can be combined to generate a true positive rate (“TPR”) and a true negative rate (“TNR”). The overall score (“Score”) in this example may be calculated as a product of the true negative rate and the true positive rate. The higher the score, the better the model configuration performs at detecting the likelihood of a hotspot.

Note that the table 700 only illustrates different combinations of the output dimensions of the different neural networks. However, it should be understood that actual simulation would vary other parameters in the configurations as well, including a number of hidden layers and different architectural connections between neural networks in the model itself. Each of these different model configurations may be trained using historical data described above and executed with the test data to generate an overall score. Although only the output dimensions are shown in table 700 for the sake of clarity, this is not meant to be limiting.

The table 702 illustrates a more exhaustive set of combinations of the different output dimensions for the CNN and the tabular network. For a given application, test data may be applied to these models and simulated to generate the output scores described above. The table 702 may be populated for each combination of output dimensions that are tested. To find an optimal configuration, the method may identify a maximum score in the table 702. In this case, the maximum score (0.96) corresponds to a CNN dimension of 64 and a tabular dimension of 10. More generally, identifying the configuration in the plurality of configurations that best determines the likelihood of the hotspot may include maximizing a score or statistic indicative of model performance in a target technology, such as a product of a true negative rate and a true positive rate.

Turning back briefly to FIG. 3, the method 300 may also include using the ML model with the optimal configuration to determine a likelihood of a hotspot at the location on the semiconductor substrate (308). After the selection and training process described in FIG. 3, the chosen model configuration may be used to execute the method in FIG. 1 to predict hotspot locations for a semiconductor process.

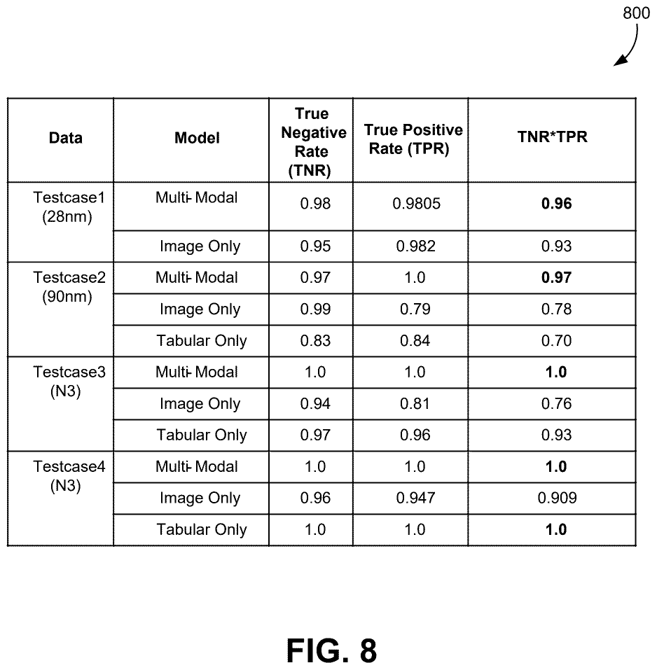

FIG. 8 illustrates a table 800 showing the performance difference between multi-modal models in comparison to models with only a single type of input, according to some embodiments. These tests were performed on various technology nodes, including 90 nm nodes, 28 nm nodes, N3 nodes, and N4 nodes. The table 800 illustrates how the multi-modal models performed equal to or better than any of the single-input models (and usually these multi-modal models performed significantly better). This represents a significant improvement in semiconductor manufacturing technology. Specifically, using a multi-modal model as described herein significantly improves the hotspot prediction and detection, which in turn reduces the number of locations that need to be examined with more time-intensive and resource-intensive processes (e.g., EBI). This improves the throughput of the manufacturing process, improves the yield of dies on the semiconductor substrate, and improves the reliability and performance of the resulting integrated circuit (IC) dies.

It should be appreciated that the specific steps illustrated in FIG. 3 provide particular methods of training and optimizing a multi-modal model according to various embodiments. Other sequences of steps may also be performed according to alternative embodiments. For example, alternative embodiments may perform the steps outlined above in a different order. Moreover, the individual steps illustrated in FIG. 3 may include multiple sub-steps that may be performed in various sequences as appropriate to the individual step. Furthermore, additional steps may be added or removed depending on the particular applications. Many variations, modifications, and alternatives also fall within the scope of this disclosure.

FIG. 9 illustrates an exemplary controller 900, in which various embodiments may be implemented. The controller 900 may be used to implement any of the computer systems, processors, controllers, systems-on-a-chip, or other processing means described herein. For example, any of the methods described above may be performed by the controller 900. The controller 900 may also be distributed, with various processors, memory devices, and other hardware/software distributed between a workstation, a chamber controller, a server, and so forth. Alternatively, any or all of the hardware/software illustrated in FIG. 9 may be co-located on a single computing system. As shown in the figure, controller 900 includes a processing unit 904 that communicates with a number of peripheral subsystems via a bus subsystem 902. These peripheral subsystems may include a processing acceleration unit 906, an I/O subsystem 908, a storage subsystem 918 and a communications subsystem 924. Storage subsystem 918 includes tangible computer-readable storage media 922 and a system memory 910.

Bus subsystem 902 provides a mechanism for letting the various components and subsystems of controller 900 communicate with each other as intended. Although bus subsystem 902 is shown schematically as a single bus, alternative embodiments of the bus subsystem may utilize multiple buses. Bus subsystem 902 may be any of several types of bus structures including a memory bus or memory controller, a peripheral bus, and a local bus using any of a variety of bus architectures. For example, such architectures may include an Industry Standard Architecture (ISA) bus, Micro Channel Architecture (MCA) bus, Enhanced ISA (EISA) bus, Video Electronics Standards Association (VESA) local bus, EtherCAT, and Peripheral Component Interconnect (PCI) bus, which can be implemented as a Mezzanine bus manufactured to the IEEE P1386.1 standard.

Processing unit 904, which can be implemented as one or more integrated circuits (e.g., a conventional microprocessor or microcontroller), controls the operation of controller 900. One or more processors may be included in processing unit 904. These processors may include single core or multicore processors. In certain embodiments, processing unit 904 may be implemented as one or more independent processing units 932 and/or 934 with single or multicore processors included in each processing unit. In other embodiments, processing unit 904 may also be implemented as a quad-core processing unit formed by integrating two dual-core processors into a single chip.

In various embodiments, processing unit 904 can execute a variety of programs in response to program code and can maintain multiple concurrently executing programs or processes. At any given time, some or all of the program code to be executed can be resident in processing unit 904 and/or in storage subsystem 918. Through suitable programming, processor(s) 904 can provide various functionalities described above. Controller 900 may additionally include a processing acceleration unit 906, which can include a digital signal processor (DSP), a special-purpose processor, and/or the like.

I/O subsystem 908 may include user interface input devices and user interface output devices. User interface input devices may include a keyboard, pointing devices such as a mouse or trackball, a touchpad or touch screen incorporated into a display, a scroll wheel, a click wheel, a dial, a button, a switch, a keypad, audio input devices with voice command recognition systems, microphones, and other types of input devices.

User interface output devices may include a display subsystem, indicator lights, or non-visual displays such as audio output devices, etc. The display subsystem may include a flat-panel device, such as that using a liquid crystal display (LCD) or plasma display, a projection device, a touch screen, and the like. In general, use of the term “output device” is intended to include all possible types of devices and mechanisms for outputting information from controller 900 to a user or other computer. For example, user interface output devices may include, without limitation, a variety of display devices that visually convey text, graphics and audio/video information such as monitors, printers, speakers, headphones, plotters, voice output devices, modems, and/or the like.

Controller 900 may include a storage subsystem 918 that comprises software elements, shown as being currently located within a system memory 910. System memory 910 may store program instructions that are loadable and executable on processing unit 904, as well as data generated during the execution of these programs.

Depending on the configuration and type of controller 900, system memory 910 may be volatile (such as random access memory (RAM)) and/or non-volatile (such as read-only memory (ROM), flash memory, etc.) The RAM typically contains data and/or program modules that are immediately accessible to and/or presently being operated and executed by processing unit 904. In some implementations, system memory 910 may include multiple different types of memory, such as static random access memory (SRAM) or dynamic random access memory (DRAM). In some implementations, a basic input/output system (BIOS), containing the basic routines that help to transfer information between elements within controller 900, such as during start-up, may typically be stored in the ROM. By way of example, and not limitation, system memory 910 also illustrates application programs 912, which may include client applications, Web browsers, mid-tier applications, relational database management systems (RDBMS), etc., program data 914, and an operating system 916.

Storage subsystem 918 may also provide a tangible computer-readable storage medium for storing the basic programming and data constructs that provide the functionality of some embodiments. Software (programs, code modules, instructions) that when executed by a processor provide the functionality described above may be stored in storage subsystem 918. These software modules or instructions may be executed by processing unit 904. Storage subsystem 918 may also provide a repository for storing data used in accordance with some embodiments.

Storage subsystem 918 may also include a computer-readable storage media reader 920 that can further be connected to tangible computer-readable storage media 922. Together, and optionally in combination with system memory 910, tangible computer-readable storage media 922 may comprehensively represent remote, local, fixed, and/or removable storage devices plus storage media for temporarily and/or more permanently containing, storing, transmitting, and retrieving computer-readable information.

Tangible computer-readable storage media 922 containing code, or portions of code, can also include any appropriate media, including storage media and communication media, such as but not limited to, volatile and non-volatile, removable and non-removable media implemented in any method or technology for storage and/or transmission of information. This can include tangible computer-readable storage media such as RAM, ROM, electronically erasable programmable ROM (EEPROM), flash memory or other memory technology, including optical storage, magnetic storage, magnetic disk storage or other magnetic storage devices, or other tangible computer readable media. This can also include nontangible computer-readable media, such as data signals, data transmissions, or any other medium which can be used to transmit the desired information, and which can be accessed by computing system 900.

By way of example, tangible computer-readable storage media 922 may include a hard disk drive that reads from or writes to non-removable, nonvolatile magnetic media, a magnetic disk drive that reads from or writes to a removable, nonvolatile magnetic disk, and an optical disk drive that reads from or writes to a removable, nonvolatile optical disk such as a CD ROM, DVD, and Blu-Ray® disk, or other optical media. Tangible computer-readable storage media 922 may include, but is not limited to, flash memory cards, universal serial bus (USB) flash drives, secure digital (SD) cards, disks, digital video tape, and the like. Tangible computer-readable storage media 922 may also include, solid-state drives (SSD) based on non-volatile memory such as flash-memory based SSDs, enterprise flash drives, solid state ROM, and the like, SSDs based on volatile memory such as solid state RAM, dynamic RAM, static RAM, DRAM-based SSDs, magnetoresistive RAM (MRAM) SSDs, and hybrid SSDs that use a combination of DRAM and flash memory based SSDs. The disk drives and their associated computer-readable media may provide non-volatile storage of computer-readable instructions, data structures, program modules, and other data for controller 900.

Communications subsystem 924 provides an interface to other computer systems and networks. Communications subsystem 924 serves as an interface for receiving data from and transmitting data to other systems from controller 900. For example, communications subsystem 924 may enable controller 900 to connect to one or more devices via the Internet. In some embodiments communications subsystem 924 can include radio frequency (RF) transceiver components for accessing wireless voice and/or data networks (e.g., using cellular telephone technology, advanced data network technology, such as 3G, 4G or EDGE (enhanced data rates for global evolution), WiFi (IEEE 802.11 family standards, or other mobile communication technologies, or any combination thereof), and/or other components. In some embodiments, communications subsystem 924 can provide wired network connectivity (e.g., Ethernet) in addition to or instead of a wireless interface.

In some embodiments, communications subsystem 924 may also receive input communication in the form of structured and/or unstructured data feeds 926, event streams 928, event updates 930, and the like on behalf of one or more users who may use controller 900.

Additionally, communications subsystem 924 may also be configured to receive data in the form of continuous data streams, which may include event streams 928 of real-time events and/or event updates 930, that may be continuous or unbounded in nature with no explicit end. Examples of applications that generate continuous data may include, for example, sensor data applications, financial tickers, network performance measuring tools (e.g. network monitoring and traffic management applications), clickstream analysis tools, automobile traffic monitoring, and the like.

Communications subsystem 924 may also be configured to output the structured and/or unstructured data feeds 926, event streams 928, event updates 930, and the like to one or more databases that may be in communication with one or more streaming data source computers coupled to controller 900.

Due to the ever-changing nature of computers and networks, the description of controller 900 depicted in the figure is intended only as a specific example. Many other configurations having more or fewer components than the system depicted in the figure are possible. For example, customized hardware might also be used and/or particular elements might be implemented in hardware, firmware, software (including applets), or a combination. Further, connection to other computing devices, such as network input/output devices, may be employed. Based on the disclosure and teachings provided herein, other ways and/or methods to implement the various embodiments should be apparent.

As used herein, the terms “about” or “approximately” or “substantially” may be interpreted as being within a range that would be expected by one having ordinary skill in the art in light of the specification. By way of example, these terms may imply a 10% variation above or below a stated value (i.e., “approximately 50” would imply a range between 45 and 55).

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have beeen described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A method for predicting hotspots on semiconductor substrates, the method comprising:
receiving first data associated with a manufacturing a semiconductor substrate, wherein the first data comprises a first data type, and the first data is associated with a location on the semiconductor substrate;
receiving second data associated with the manufacturing of the semiconductor substrate, wherein the second data comprises a second data type that is different from the first data type, and the second data is associated with the location on the semiconductor substrate;
providing the first data and the second data to a trained machine-learning model, wherein the trained machine-learning model comprises:
a first neural network configured to process data of the first data type;
a second neural network configured to process data of the second data type; and
an output layer that generates a likelihood of a hotspot at the location on the semiconductor substrate based at least in part on outputs of the first neural network and the second neural network; and
causing an inspection process to be performed at the location on the semiconductor substrate based at least in part on the output of the trained machine-learning model.

2. The method of claim 1, wherein the inspection process comprises performing an eBEAM Wafer Inspection (EBI) at the location on the semiconductor substrate based on the likelihood of the hotspot at the location.

3. The method of claim 1, wherein the inspection process comprises an Optical Wafer Inspection (OPWI) being performed on the semiconductor substrate, and correlating a result of the OPWI at the location with the likelihood of the hotspot at the location to reduce the probability of a false positive.

4. The method of claim 1, wherein the first data comprises images based on a layout design file for the semiconductor substrate.

5. The method of claim 4, wherein the first neural network comprises a convolutional neural network (CNN) configured to identify features in the images of the semiconductor substrate that are associated with hotspots.

6. The method of claim 1, wherein the second data comprises tabular data from a design file for the semiconductor substrate.

7. The method of claim 1, wherein the second data comprises tabular data from a metrology file for the semiconductor substrate.

8. The method of claim 1, wherein the second neural network comprises an attention-based neural network configured to process tabular data.

9. A method of training machine-learning models to generate likelihoods of hotspots at locations on semiconductor substrates, the method comprising:
defining a plurality of configurations for a machine-learning model, wherein each of the plurality of configurations define:
first parameters for a first neural network configured to process first data of a first data type, wherein the first data is associated with a manufacturing of a semiconductor substrate and associated with a location on the semiconductor substrate;
second parameters for a second neural network configured to process second data of a second data type that is different from the first data type, wherein the second data is associated with the manufacturing of the semiconductor substrate and associated with a location on the semiconductor substrate; and
connections between components of the machine-learning model including the first neural network and the second neural network;
training instances of the machine-learning model using each of the plurality of configurations to generate likelihoods of a hotspot at the location on the semiconductor substrate;
identifying a configuration in the plurality of configurations that best determines likelihoods of hotspots on semiconductor substrates; and
using the machine-learning model with the configuration to determine the likelihoods of hotspots on semiconductor substrates.

10. The method of claim 9, wherein the first parameters comprise a dimension of an output of the first neural network.

11. The method of claim 9, wherein the first parameters comprise a number of hidden layers of the first neural network.

12. The method of claim 9, wherein the connections between the components of the machine-learning model comprise:
the first neural network and the second neural network processing data in parallel; and
outputs of the first neural network and the second neural network being combined in a set of fully connected layers that generate an output of the likelihood of the hotspot at the location on the semiconductor substrate.

13. The method of claim 9, wherein the connections between the components of the machine-learning model comprise:
the first neural network and the second neural network processing data sequentially; and
an output of the first neural network being combined with the second data to be processed by the second neural network before being processed by a set of fully connected layers that generate an output of the likelihood of the hotspot at the location on the semiconductor substrate.

14. The method of claim 9, wherein the connections between the components of the machine-learning model comprise:
the first neural network and the second neural network processing data sequentially;
an output of the first neural network being combined with the second data to be processed by the second neural network; and
an output of the second neural network being combined with the output of the first neural network in a set of fully connected layers that generate an output of the likelihood of the hotspot at the location on the semiconductor substrate.

15. The method of claim 9, wherein the connections between the components of the machine-learning model comprise:
the first neural network and the second neural network processing data in parallel; and
outputs of the first neural network and second neural network being combined in a second instance of the second neural network that generates an output of the likelihood of the hotspot at the location on the semiconductor substrate.

16. The method of claim 9, wherein identifying the configuration in the plurality of configurations that best determines the likelihood of the hotspot comprises maximizing a product of a true negative rate and a true positive rate.

17. A system comprising:
one or more processors; and
one or more memory devices storing instructions that, when executed by the one or more processors, cause the one or more processors to perform operations comprising:
receiving first data associated with manufacturing a semiconductor substrate, wherein the first data comprises a first data type, and the first data is associated with a location on the semiconductor substrate;
receiving second data associated with the manufacturing of the semiconductor substrate, wherein the second data comprises a second data type that is different from the first data type, and the second data is associated with the location on the semiconductor substrate;
providing the first data and the second data to a trained machine-learning model, wherein the trained machine-learning model comprises:
a first neural network configured to process data of the first data type;
a second neural network configured to process data of the second data type; and
an output layer that generates a likelihood of a hotspot at the location on the semiconductor substrate based at least in part on outputs of the first neural network and the second neural network; and
determining the likelihood of the hotspot at the location on the semiconductor substrate based at least in part on an output of the trained the machine-learning model.

18. The system of claim 17, wherein the second data comprises time series data from a semiconductor processing chamber used in the manufacturing of the semiconductor substrate.

19. The system of claim 17, wherein the semiconductor substrate is subdivided into a plurality of locations that include the location on the semiconductor substrate, and each of the plurality of locations comprises a rectangular subdivision of the semiconductor substrate.

20. The system of claim 17, wherein the first data is received from a first data source, and the second data is received from a second data source that is different from the first data source.
